(19) United States
(12) Patent Application Publication
(10) Pub. No.: US 2002/0003824 A1
(43) Pub. Date: Jan. 10, 2002

(54) Surface-emitting laser devices with integrated beam-shaping optics and power-monitoring detectors

(76) Inventors: Yu-Hwa Lo, San Diego, CA (US); Zuhua Zhu, San Jose, CA (US); Chenting Lin, Poughkeepsie, NY (US)

Correspondence Address: FISH & NEAVE, 1251 AVENUE OF THE AMERICAS, 50TH FLOOR, NEW YORK, NY, 10020-1105, US

(21) Appl. No.: 09/871,229

(22) Filed: May 31, 2001

Related U.S. Application Data
(60) Provisional application No. 60/208,289, filed on May 31, 2000.
(60) Provisional application No. 60/219,701, filed on Jul. 18, 2000.

(51) Int. Cl. H01S 5/00

(52) U.S. Cl. 372/50

(57) ABSTRACT

A semiconductor surface-emitting laser device has a lasing section and a beam-deflecting section. The two sections are assembled adjacent to each other in close optical and physical proximity. The lasing section includes a horizontal laser cavity having faceted ends. The cavity emits horizontally propagating a light beam through one faceted end into the adjoining beam-deflecting section. The beam-deflecting section includes two mirror surfaces. The two mirror surfaces are oriented such that the horizontally propagating light beam is redirected to propagate vertically toward the top surface of the laser device by sequential reflections off of the two mirrors. A beam-shaping micro-optics lens is disposed on the top surface of the beam-deflecting section. The micro-optic lens collimates the vertically propagating redirected light beam to generate an output beam emitted from the top surface of the laser device.

Optionally, the laser device may have an integrated power-monitoring detector. The detector may, for example, be a photodetector built in the beam-deflecting section.

This application claims the benefit of U.S. provisional patent application No. 60/208,289, filed on May 31, 2000, and U.S. provisional patent application No. 60/219,701, filed on Jul. 18, 2000, both of which are hereby incorporated by reference herein in their entireties.

### BACKGROUND OF THE INVENTION

This invention relates to the field of semiconductor lasers, and more particularly to surface-emitting semiconductor lasers useful in optical fiber communication systems.

Semiconductor Edge Emitting Lasers (EELs) have been historically used as light sources in optical fiber communication systems. To meet a universally increasing demand for data transmission links and telecommunications there is a commercial need to fully exploit the capabilities of optical fiber communication systems. The amount of data and distance over which signals can be transmitted over optical fibers is related to the wavelength of the carrier light beam. For example, the standard carrier light wavelengths for optical fiber communication systems, as a function of the reach of the systems, are progressively higher into the near infrared radiation band. The standard carrier wavelengths are, for example, about 820 nm for short haul applications, about 1.31 μm for intermediate haul applications, and about 1.55 μm for long haul applications. The increasing demand for faster and cheaper data transmission links and telecommunications has highlighted deficiencies of EELs used at light sources at these near infrared wavelengths. These deficiencies include, for example, high manufacturing costs, and less than optimal beam cross-section for coupling to optical fibers.

EEL devices are generally mass produced using semiconductor wafers. Several horizontal dielectric waveguides may be diffused into or epitaxially grown on the surface of a wafer. The wafer is cleaved to section the dielectric waveguides into lasing cavities. Cleaved wafer facets at the ends of the waveguide sections serve as laser cavity mirrors. Even though EEL manufacturing processes seem straight forward, conventionally manufactured EEL devices must undergo heavy screening or testing for reliability. The structure of EEL devices does not lend itself to on-wafer testing of individual laser devices. Typically, the wafer is diced to separate individual laser devices. Each individual laser device is then mounted on a carrier and tested before being packaged for sale. This unavoidable individual testing of EEL devices contributes significantly to manufacturing costs.

Further, light emission in EEL devices is parallel to the wafer surface and out from the side through cleaved ends of the laser cavities. The emitted light beams are divergent, and have elliptical cross-sections. The elliptical cross-sections are not suitable for efficient coupling of the light beams to optical fibers. Additional external focusing or beam-shaping optics must be used to couple the light beams to optical fibers. For wavelengths in the near infrared band such as 1.3 μm and 1.55 μm the focusing optics can be expensive, technologically complex and difficult.

In addition to these deficiencies, EELs generally have poor lasing mode stability. Traditionally, separate back facet power-monitoring detectors are used to monitor laser output and to provide feedback to laser drive circuitry for stabilizing laser output. Even with feedback control laser stability is poor at near infrared wavelengths.

Another type of laser, the so-called vertical cavity surface-emitting laser (VCSEL), has properties which are more desirable than those of EELs for optical fiber communication systems. VSCELs also are made from semiconductor wafers. Several vertical laser cavities perpendicular to the wafer surface are epitaxially grown on the wafer. Light emission is perpendicular to the surface of the wafers. The light beams emitted by the vertical cavities have circular cross-sections. Light beams with circular cross-sections are relatively easy to couple to optical fibers. External beam-shaping optics may not be necessary. Moreover, the structure of the VCSELs and their manufacturing processes lend themselves to on-wafer testing of individual laser devices. Unlike EEL devices, VCSEL devices do not have to be diced and individually mounted for testing. On-wafer testing leads to manufacturing cost savings. Further, the VCSELs operating at 850 nm have good spectral characteristics.

FIG. 1 illustrates the structure of a typical VCSEL device operating at about 850 nm wavelength. VCSEL 1 is epitaxially grown on a gallium arsenide (GaAs) substrate 13 and includes a top distributed Bragg reflector (DBR) 10, a quantum-well active region 11, a bottom DBR 12. Both DBR 10 and 12 are made of alternating layers of GaAs and aluminum gallium arsenide (AlGaAs). The two DBRs act as mirrors and define a vertical lasing cavity in between themselves. VSCEL 1 produces output light beam 14 perpendicular to the wafer surface through top DBR 10. A small fraction of output light beam 14 may be diverted and monitored by a separate photodetector for feedback control (not shown).

Recent advances in compound semiconductor (e.g., GaAs/AlGaAs) epitaxial growth technology and refinements of other manufacturing processes have enabled low-cost mass production of VSCELs operating at about 850 nm. These low-cost VSCELs with their superior performance have almost completely supplanted the use of EELs, for example, in short haul communication applications that use the nominal 850 nm carrier wavelength.

However, VCSELs devices do not operate well at the higher wavelengths of 1.3 μm and 1.55 μm that are suitable, for example, for intermediate and long haul applications, respectively. High optical cavity losses, and high non-radiative recombination rates combined with decreased efficiency of GaAs/AlGaAs DBR mirrors at these higher wavelengths result in poor VCSEL performance.

Some other surface-emitting laser (SEL) structures that have horizontal lasing cavities are of current research interest. These SEL structures incorporate integrated on-wafer reflective structures in an attempt to mitigate the need for external beam-shaping optics. The reflective structures in these SELs are used to redirect horizontally propagating light radiation to a vertical direction. These SEL structures may be broadly categorized as either grating-coupled or beam-deflecting mirror types of SELs, depending on the type of reflective structure used.

The reflective structures in the grating-coupled SELs are gratings etched into the wafer surface above the horizontal lasing cavities. FIG. 2 illustrates the structure of a typical grating-coupled laser. Laser 2 consists of grating 20 disposed on top of lasing cavity 21. Metal electrode contacts 22 and 23 disposed on the top and bottom surfaces of laser 2, respectively, are connected to laser driver circuits (not shown). Second-order diffraction effects couple in-plane light radiation propagating in laser cavity 21 to produce output beam 24 perpendicular to the wafer surface.

The reflective structures in beam-deflecting mirror type SELs are typically 45-degree etched mirrors. FIGS. 3 and 4 show the structures of lasers 3 and 4, respectively. Both lasers have 45-degree etched mirrors for beam deflection. In laser 3, etched mirror 31 is part of lasing cavity 33. Mirror 31 deflects in-plane light upward by 90 degrees toward dielectric mirror 30. Dielectric mirror 30 transmits a portion of the deflected light as output beam 34, and reflects another portion back to lasing cavity 33. In laser 4, etched mirror 41 is external to lasing cavity 42. One end of lasing cavity 42 is a 90-degree etched surface 40. Mirror 41 deflects the light beam exiting etched surface 40 upward by 90 degrees to form output beam 44.

Both the typical grating-coupled and the beam-deflecting mirror types of SELs exhibit unsatisfactory laser performance. The laser performance is poor at least in part because the reflecting structures often intrude on the lasing action of the laser cavity. In grating-coupled SELs poor laser performance results, for example, from increased scattering loss and non-uniform current injection into the light-coupling region underneath the grating. Beam-deflecting mirror type SELs which have an angled mirror as part of the lasing cavity (e.g., laser 3 FIG. 3) tend to have large optical cavity losses. The large cavity losses result in undesirable high laser threshold current and low output power.

Laser performance may be poor even when the 45-degree mirror is external to the laser cavity which has perpendicular edges (e.g., laser 4, FIG. 4). The 45-degree mirror does not improve the divergence or the elliptical cross-section of the emitted light beam. Therefore, having a 45-degree mirror in the laser structure does not improve the efficiency of coupling light to an optical fiber. External beam-correction and focusing optics may still have to be used to couple output light beams to an optical fiber.

Additionally, the etched reflective structures of these SEL types present severe challenges in manufacturing. Precise and reproducible etching of 45-degree mirrors in close proximity to perpendicular cavity ends is difficult, for example, because the 45-degree plane is not a naturally terminating etch plane in most semiconductors.

It is therefore desirable to have new surface-emitting laser device structures that have good operating characteristics at near infra-red wavelengths, are amenable to on-wafer testing, and provide efficient beam coupling to optical fibers.

### SUMMARY OF THE INVENTION

In accordance with the present invention, surface-emitting laser devices with integrated beam-shaping optics are provided. The beam-shaping optics use the optical phenomenon of total internal reflection, transparent substrates, and refractive or diffractive micro-optic lenses to generate surface-emitted light output beams.

The inventive laser device structure includes a lasing section and a beam-deflecting section. The two sections are maintained in close physical and optical proximity for efficient transmission of laser radiation from the first section to the later section.

The lasing section contains a horizontal lasing cavity, which can be similar to those in conventional edge-emitting laser diodes. The lasing cavity is generally parallel to the top surface of the device. Cleaved or etched facets form the mirror ends of the lasing cavity. Light beams emitted by the lasing cavity exit one end of the lasing section and propagate horizontally into the adjoining beam-defection section of the device.

The beam-deflection section is made of a substrate which is transparent to the emitted light beams. A reflective mirror is formed on the bottom surface of the beam-deflection section. The beam-deflecting section includes another mirror or deflecting surface in the path of the horizontally propagating light beams transmitted by the lasing section. This deflecting surface may be formed by a crystallographically terminating etch plane of the substrate crystal. The deflecting surface is designed to make an angle with the horizontal which is greater than the critical angle for total internal reflection. The horizontally propagating light beams (from the lasing section) incident on the deflecting surface undergo total internal reflection and are redirected downward toward the bottom surface. The reflective mirror at the bottom surface reflects downward incident light beams upwards toward the top surface of the laser device.

The beam-deflection section includes a micro-optic lens disposed on its top surface. This lens may be a refractive lens, a diffraction lens, or a combination. The lens may be designed to collimate (i.e., reduce the divergence) of upwardly redirected light beams emerging through the top surface. The lens design may also be tailored so that the lens output beam has a more circular cross-section suitable for efficient coupling to optical fibers.

Optionally, a photodetector for monitoring the laser device output power may be integrated into the device structure. The photodetector may, for example, be a photodiode formed by depositing a metal electrode on a portion of the beam-deflecting section of the laser device.

The inventive laser devices may be fabricated using common semiconductor device manufacturing processes. For example, the laser devices may be made from common semiconductor wafer substrates that have epitaxial waveguide layers grown on them. The lasing and the beam-deflecting sections of the laser devices may be made from adjacent cleaved substrate pieces. The two sections may be assembled in close proximity by rejoining cleaved wafer pieces along the cleavage facets. Alternatively, the lasing and the beam-deflecting sections may be formed from adjacent uncleaved substrate pieces, but which are delimited by narrow trenches etched through the epitaxial layers.

Further, for example, common wet etching techniques using anisotropic etchants may be used to form the deflection surface which is used for total internal reflection of light. Suitable anisotropic etchants such as HBr solutions may be used to form V-groove shaped etch pits, the sides of which are crystallographically terminating etch planes. A suitably oriented side may be used as the deflecting surface.

Further, common semiconductor processing materials such as photo-resists, oxides or nitrides may be used to form the micro-optic lens disposed on the top surface of the device. For example, the micro-optic lens may be formed by resist reflow. The parameters of the resist reflow processes may be suitably adjusted to obtain lenses with a focal length suitable for collimating the output light beam.

The inventive laser devices operating at near infrared wavelengths are expected to generate output beams suitable for direct coupling to optical fibers. The integrated beam-shaping optics of the device structures minimizes the need for external beam-shaping or focusing optics.

### BRIEF DESCRIPTION OF THE DRAWINGS

Further features of the invention, its nature and various advantages will become apparent from the following detailed description, taken in conjunction with the accompanying drawings, in which like reference characters refer to like parts throughout, and in which:

FIG. 1 is a cross-sectional view of a conventional vertical cavity surface-emitting laser device structure;

FIG. 2 is a cross-sectional view of a conventional grating-coupled surface-emitting laser device structure;

FIG. 3 is a cross-sectional view of a conventional surface-emitting laser device structure with an integrated 45-degree mirror as part of the lasing cavity;

FIG. 4 is a cross-sectional view of a conventional surface-emitting laser device structure with an integrated 45-degree mirror external to the lasing cavity;

FIG. 5a is a cross-sectional view of a surface-emitting laser device structure in accordance with the principles of this invention;

FIG. 5b is a cross-sectional view of another surface-emitting laser device structure in accordance with the principles of this invention;

FIG. 5c is a plan view of the surface-emitting laser device structures shown in FIGS. 5a.

FIG. 6a is a cross sectional view of a surface-emitting laser device structure including an integrated power-monitoring photodiode, in accordance with the principles of this invention; and

FIG. 6b is a plan view of the surface-emitting laser structure of FIG. 6a.

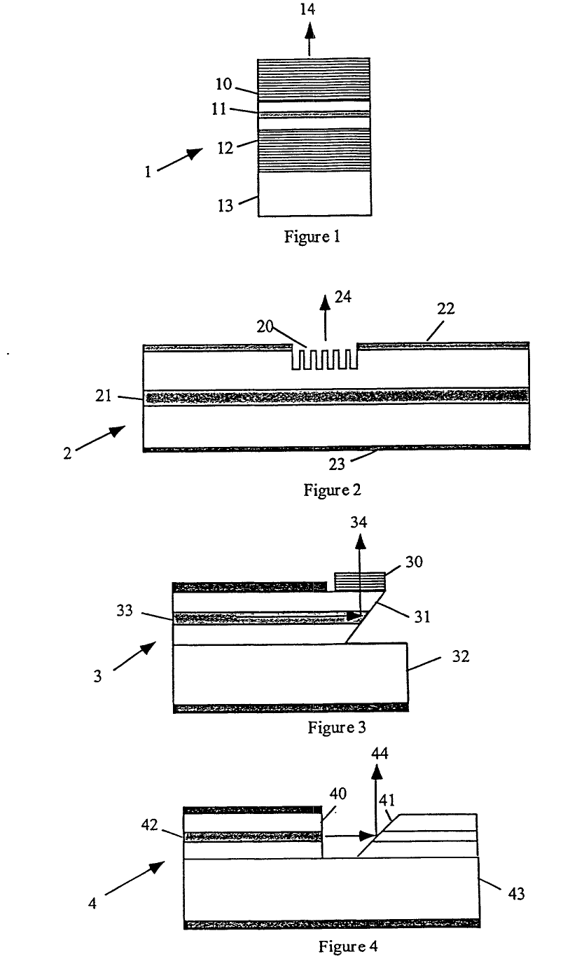

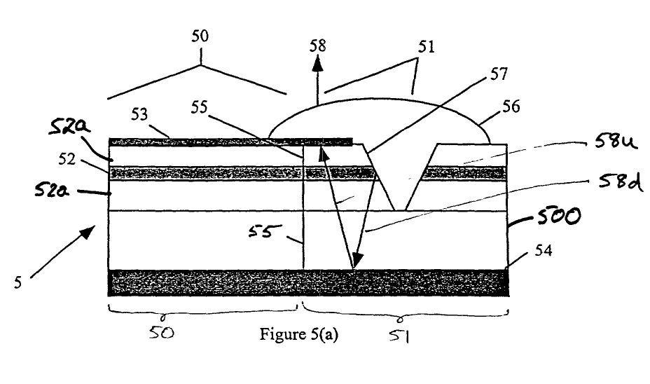

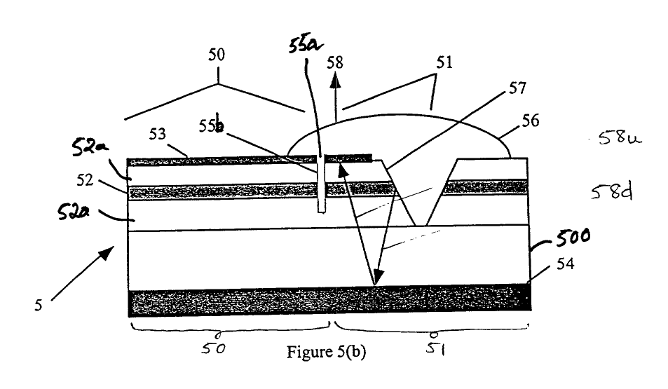

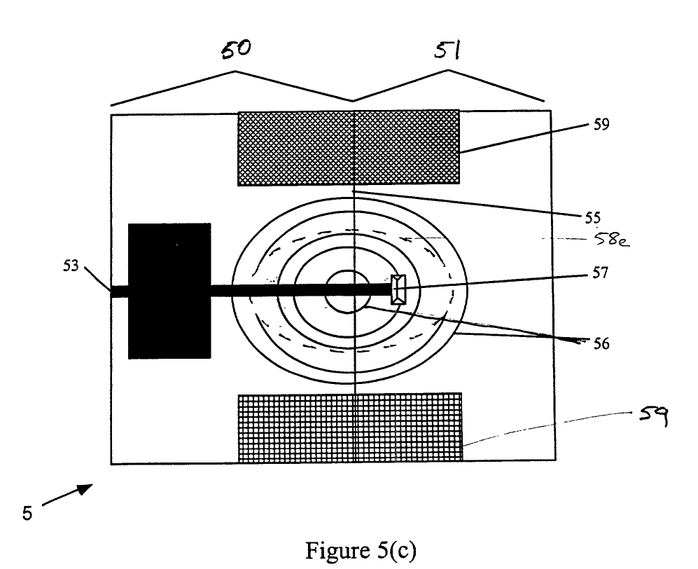

### DETAILED DESCRIPTION OF THE INVENTION

The present invention is described herein in the context of lasers which are based, for example, on the indium phosphide (InP) material system and which are designed to operate at near infrared wavelengths (e.g., at 1.3 μm or 1.55 μm wavelengths). InP substrates are suitable for making these lasers because compound-semiconductor epitaxial layers can be readily grown on them. InP substrates also have the property of being transparent to light radiation at about 1.3 μm and 1.55 μm wavelengths. This property may be exploited for beam-shaping and correction optics.

However, references to the InP material system and to specific operating wavelengths are made only for purposes of illustration, with the understanding that the inventive principles of the present invention are applicable to all material systems that may be used for making semiconductor lasers and to other operating wavelengths.

The inventive surface-emitting laser device structures are made from InP substrate wafers on which epitaxial waveguide and cladding layers are grown. Each laser device includes a horizontal lasing section and a beam-deflecting section. Both of which may be made, for example, from adjacent pieces of a substrate. The two sections are maintained in close proximity and may be mechanically joined.

The lasing section contains a horizontal waveguide section or cavity substantially parallel to the top surface of the substrate. A pair of facets that are generally perpendicular to the top surface form the mirror ends of the lasing cavity. The facets may be made by cleaving or etching the substrate or by any other suitable technique. The lasing action of the cavity may be similar to that of conventional EELs in that light emission is parallel to the wafer surface and perpendicular to a mirror end.

Light beams emitted by the lasing section propagate horizontally into the adjoining beam-deflecting section. The latter section contains an array of deflecting surfaces (mirrors). The deflecting surfaces are arranged in sequence and oriented such that the horizontally emitted light beam is redirected to propagate in a generally vertical direction. The vertically redirected beam emerges or exits from the top surface as the device's output beam. As will be described in greater detail below, the beam-deflecting section exploits the phenomena of total internal reflection and the transparency of InP to near infrared wavelengths to redirect the emitted light beams. Further, a portion of the beam-deflecting section may be used as a power-monitoring photodetector to provide feedback to laser drive circuits for laser output stabilization.

The lasing section and the beam-deflecting section made, for example, from adjacent substrate pieces, are distinctly separate even though they are placed in close proximity. The adjacent pieces from which the two sections are made may be cleaved apart to form laser cavity facets, and then mechanically rejoined. Unlike dicing, cleaving semiconductors along crystal planes does not generate material loss. Adjacent cleaved pieces may be rejoined with a gap of less than about a thousand angstroms between them. Known techniques for cleaving and rejoining semiconductor facets such as wafer bonding may be used. Using such techniques, it also may be possible to use non-adjacent cleaved pieces of the substrate for making the two sections. If for example, the cleaved facets of the non-adjacent pieces have suitable mutually conforming shapes, they may be satisfactorily rejoined.

Alternatively, the lasing section and the beam-deflecting section may be delimited by etching a vertical trench between the adjacent pieces from which the two sections are made. The vertical trench may extend through the epitaxial waveguide layers on the substrate. A trench sidewall may provide an etched facet for one end of the lasing section.

The close proximity of the two sections in the device ensures efficient transmission of emitted light from the lasing section to the beam-deflecting section. Light transmission or coupling efficiencies of about 85% may be expected. At the same time, the distinct separation of the two sections by cleaved or etched facets minimizes any adverse effect of the close proximity of the second section on the lasing action of the first section. The output power, threshold current, frequency response, and other lasing characteristics of the laser device may be determined primarily by the first section (i.e., lasing section) of the device structure.

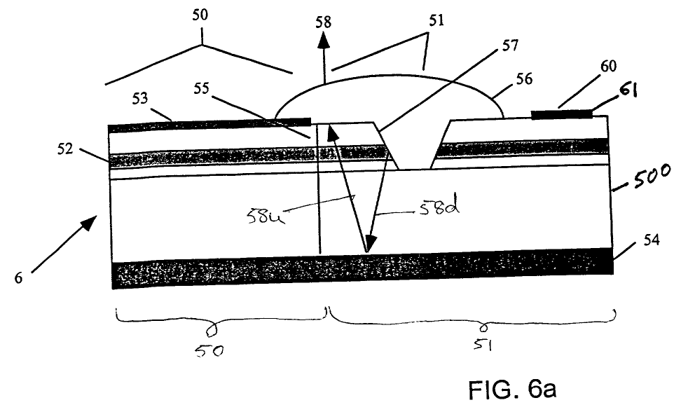

FIGS. 5a, 5b, and 5c illustrate two structural embodiments of a surface-emitting laser 5 in accordance with the present invention. Laser 5 includes an edge-emitting lasing section 50 and a beam-deflecting section 51. Both sections 50 and 51 include an active waveguide layer 52 bounded by upper and lower cladding layers 52a, and a bottom reflector/electrode 54. Top electrode 53 may extend over lasing section 50, and may also extend over section 51 as shown in the FIGS. 5a, 5b and 5c. Electrodes 53 and 54 are connected to suitable laser driver circuits (not shown). Beam-deflecting section 51 further includes a light deflecting surface 57 and a micro-optic lens 56.

Laser 5 may be fabricated on InP substrate 500 using conventional semiconductor processing techniques, for example, to grow epitaxial layers and deposit metal electrode layers. The same epitaxial materials that are traditionally used in conventional InP-based EELs may be used. Cladding layers 52a may, for example, be formed using p− and − doped InP. Active waveguide layer 52 may, for example, be made of a series of one or more AlInGaAs or InGaAsP quantum wells or be made of a bulk InP layer about 2000 Å thick. To improve laser performance, a graded index region may be formed on either side of active layer 52 to enhance the optical confinement (not shown). A low-bandgap compound semiconductor (e.g., InGaAs) layer (not shown) may also be formed on the top of the epitaxial cladding layers to facilitate ohmic contact by metal electrode 53.

In the embodiment shown in FIG. 5a and 5c, sections 50 and 51 abut each other along cleaved facets 55. An InP substrate wafer is typically about 350 μm thick. To facilitate later cleaving of adjacent pieces from which sections 50 and 51 are made, the starting substrate thickness may be reduced by back lapping to a thickness of about 80 μm to 100 μm. Then, the lapped surface may be polished to create a reflective back surface. After cleaving the adjacent pieces, sections 50 and 51 may be rejoined with a gap of less than about a thousand angstroms between them. Sections 50 and 51 may be rejoined, as mentioned earlier, using known techniques such as wafer bonding. Optional structure 59 (FIG. 5c) also may be used to mechanically hold sections 50 and 51 together. Structure 59 may, for example, be made of plated metal films, epoxy, resists, or any other suitable material.

In the embodiment shown in FIG. 5b, sections 50 and 51 are disposed adjacent to each other on the same uncleaved substrate 500, but are separated by a vertical trench 55a. Trench 55a extends downward from the top surface of the wafer through the epitaxial layers on top of substrate 500. Trench 55a may be about 5 to 6 μm deep. This depth is substantially less than the lapped substrate thickness of about 80 μm to 100 μm. Trench 55a may be formed by etching. The walls of trench 55a may be etched facets 55b which are generally perpendicular to a horizontal axis through active portion 52. Using a trench to delimit sections 50 and 51 may simplify the fabrication of the inventive laser device structures, since cleaving and rejoining processes are avoided.

Any suitable processing technique may be used to form trench 55a. For example, conventional dry etching processes such as reactive ion etching (RIE), chemical assisted ion beam etching (CAIBE), electron cyclotron resonance etching (ECR), and inductive coupled plasma etching (ICP) may be used for etching trench 55a. The close proximity of sections 50 and 51 necessary for efficient optical coupling may require that trench 55a be narrow. The narrowness of trench 55a may lead to masking effects and other deleterious process effects during etching. The masking effects and the other deleterious process effects may result in damage to etched facets 55b. However, with sufficient care during processing, damage to etched facets 55b may be avoided. Also, continuing advances in ECR, ICP, and other dry etching techniques and chemistries show promising process capability for routinely etching narrow trenches with high-quality facets. For example, trenches as narrow as 1 μm across between sections 50 and 51 have been etched (in InP) by ICP using HBr-based gases as the etching gases instead of the more commonly used CH₄/H₂ gases.

For the embodiments of laser 5 shown in FIGS. 5a and 5b, either respective cleaved facet 55 or respective etched facet 55b defines one end of a lasing cavity formed by active portion 52 in lasing section 50. In operation, light emission in laser 5 occurs perpendicular to facet 55 (or facet 55b), and propagates horizontally toward deflecting surface 57 (i.e., toward the right in FIGS. 5a and 5b).

Deflecting surface 57 may be formed by a crystallographically terminating etch plane. Surface 57 may be formed using any suitable dry etching techniques such as RIE, ECR, ICP, CAIBE, and ion milling. Surface 57 also may be formed by wet chemical etching using, for example, hydrogen bromide (HBr) solution as an etchant. Anisotropic etchants such as HBr solutions may be suitable for making self-limiting V-groove shaped etch pits. The sides of the V-groove shaped etch pits are crystallographically terminating etch planes. One side of a sufficiently large V-groove shaped etch pit may serve as deflecting surface 57.

The terminating etch plane may be a suitable crystallographic plane chosen to exploit the phenomenon of total internal reflection. The crystallographic plane is chosen such that the angle it forms with a horizontal plane (parallel to the top surface) through active portion 52 exceeds the critical angle for total internal reflection. Because active portion 52 has a finite cross-sectional area and light radiation emitted from facet 55 is divergent, not all of the emitted light is incident on surface 57 at the same angle. However, because of the close proximity of the lasing section 50 and surface 57, most, if not all, of the emitted light is likely to be incident at angles greater than the critical angle. Therefore, most of the emitted light incident on surface 57 is likely to undergo total internal reflection, and to be directed through transparent substrate 500 toward bottom reflector 54 (e.g., beam 58d). Reflection efficiencies as high as 80% may be obtained with a suitably formed surface 57.

Bottom reflector 54 redirects the light incident on it in a generally upward direction (e.g., beam 58u) toward the top wafer surface on which micro-optic lens 56 is disposed. Bottom reflector 54 may be suitably formed by first, as mentioned earlier, polishing the bottom surface of lapped substrate 500 to form a reflective surface, and then further coating the polished bottom surface with highly reflecting material such as aluminum. The reflective coating may be applied to the base of beam-deflecting section 52 or to all of the bottom surface of the substrate. Reflection efficiencies of 90% may be achieved using aluminum coatings.

Light reflected upward by reflector 54 is collimated by micro-optic lens 56 to produce an output beam 58 which is generally perpendicular to the wafer surface. Micro-optic lens 56 is designed to reduce beam divergence and to generate output beam 58 with a more circular cross-section (compared to the typical elliptical cross-section of edge-emitted light). Micro-optic lens 56 may use either diffraction or refraction phenomena or both. For effective parallel collimation of the output beam the focal length of micro-optic lens 56 should be about the same length as the optical path length traversed by the emitted light beam from its source (e.g., facet 55 or 55a) to lens 56 itself. This optical path length includes the distances traversed by the light beam through substrate 500 while undergoing total internal reflection off surface 57 and being reflected off bottom reflector 54 before emerging from the top surface. The optical path length may be in the range of a few hundred microns. Micro-optic lens having a focal length in the range of few hundred microns may be easily made and disposed directly on the top surface of the laser device. Generally, lens 56 is disposed on the top surface such that its optical axis is perpendicular to the surface of the wafer and is vertically aligned over the intersection of active area 52 and deflecting surface 57. In lateral or horizontal extent lens 56 is primarily disposed over beam-deflecting section 51, but also may extend sufficiently over lasing section 51 to capture all of the vertically emerging light beam spot (e.g., spot 58e FIG. 5c).

Micro-optic lens 56 may be formed at the same time as structures 59 (FIG. 5c) that hold sections 50 and 51 together are formed. For example, reflowed resist may be used to make both micro-optic lens 56 and structure 59. A resist-reflowed lens uses refractive phenomena to collimate light, and may have a generally hemispherical shape. Lens focal length is determined by the radius of curvature of the hemispherical shape. The radius of curvature of the hemispherical shape may be adjusted by controlling resist reflow parameters to obtain a desired lens focal length. The shape may also be suitably modified to reduce aberration and to achieve a more circular cross-section for output beam 58. Using resist-reflowed lenses, lens-to-optical fiber coupling efficiencies of about 20% and 60% may be achieved for single-mode fibers and multi-mode fibers, respectively.

Alternatively, lens 56 may utilize diffraction phenomena to collimate light. Diffraction lenses (e.g., Fresnel lenses) may be made, for example, by disposing suitable diffraction gratings on the top surface of the laser structure (not shown). The diffraction grating may be made, for example, by dry etching, or by deposition of material such as oxides or nitrides.

The capability of the inventive laser device structures to include an integrated beam-shaping lens is a direct consequence of the long optical path length of twice-reflected emitted light in section 51 (reflected first off surface 57 and then off bottom reflector 54). The optical path length without the total internal reflection off surface 57 and reflection off bottom reflector 54 (as in prior art beam-deflecting mirror SELS) would be considerably shorter. Micro-optic lenses with short focal lengths have correspondingly small radii of curvature. Such lenses are both difficult to make and to integrate into laser device structures.

The overall efficiency of coupling light emission from lasing section 50 to optical fibers (i.e., the percent of section 50 output power that is injected into an optical fiber) depends on designable characteristics of individual elements of the inventive laser device structures. For example, the overall efficiency depends on the efficiency of light coupling between section 50 and 51, the reflective efficiencies of surface 57 and bottom reflector 54, and the coupling efficiency of lens 56. These individual element characteristics may be optimized by design of each individual element. For example, reflective efficiency of bottom reflector 54 may be increased by using high reflectivity multi-layer coatings instead of using a single aluminum metal coating mentioned earlier.

Still, using the numbers for the efficiency of light coupling between section 50 and 51 (85%), the reflective efficiencies of surface 57 and bottom mirror 54 (80% and 90%, respectively), and the coupling efficiency of lens 56 (20% for single-mode fibers, and 60% for multi-mode fibers) that were mentioned earlier in the description, the inventive laser devices may be estimated to have an overall coupling efficiency of about 12% for single-mode optical fibers and about 37% for multi-mode optical fibers. With these coupling efficiencies, the inventive laser devices may be satisfactorily used for optical fiber data transmission and telecommunication applications without requiring use of expensive external beam-shaping or focusing optics.

In addition to external beam-shaping or focusing optics, traditional laser modules also often use separate power-monitoring detectors for monitoring laser output and to provide feedback to stabilize laser output (e.g., back facet power-monitoring detectors used with conventional EELs). Conventional separate power-monitoring detectors that are suitable for 1.3 μm and 1.55 μm wavelengths are expensive InGaAs or Ge photodetectors. As explained below following a discussion of the typical dimensions of sections 50 and 51, the inventive laser device structures may include integrated power-monitoring detectors. Integrating power-monitoring detectors with the laser device structures obviates the need for, and the costs associated with, separate power-monitoring detectors that are used with traditional laser modules.

Lasing section 50 and the beam-deflecting section 51 may each be about a few hundred microns long. The two sections may have unequal lengths. Lasing section 50 may, for example, be 300 μm long, while beam-deflecting section 51 may, for example, be 150 μm long. The length of lasing section 50 is primarily determined by the designed length of the lasing cavity it contains. However, only a portion of beam-deflecting section 51 is designed or used for beam deflection. This portion extends from lasing section 50 to deflecting surface 57 and is only a fraction of the total length of section 51. For example, in a beam-deflecting section 51 which is about 150 μm long, the portion used for beam deflection may be only about 30 μm long. The rest of the length of beam deflection section 51 may be necessary for etching surface 57, for mechanical stability, and further, for example, for handling convenience during processing.

Portions of beam-deflecting section 51 not used for beam deflection may optionally be used for an integrated power-monitoring detector. This power-monitoring detector may be used to monitor the laser output power and to provide feedback to laser driver circuits for stabilizing laser output.

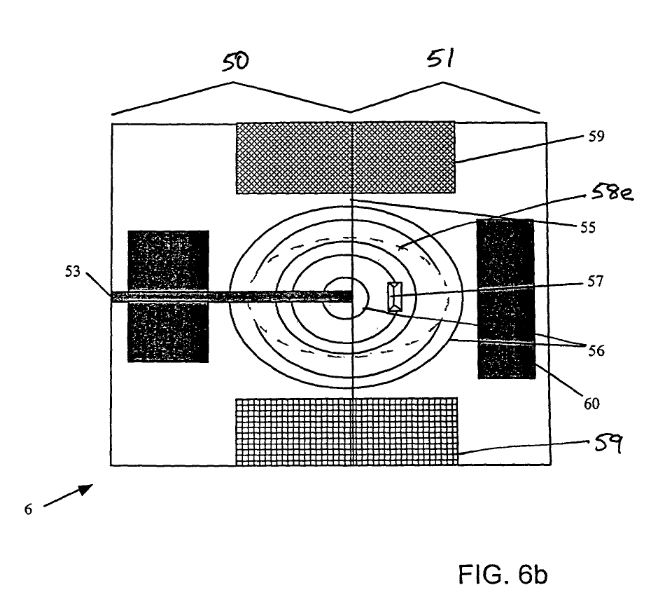

FIGS. 6a and 6b illustrate an embodiment of the inventive laser device structure which includes an integrated power-monitoring detector. Laser 6 includes lasing section 50 and beam-deflecting section 51 both of which may be similar to those of laser 5 described above (FIGS. 5a, 5b, and 5c). However, beam-deflecting section 51 of laser 6 further includes power-monitoring detector 60. Detector 60 may be a photodiode formed by disposing electrode 61 on the top surface of beam-deflecting section 51. Electrode 61 is isolated from top electrode 53 which extends only over lasing section 50.

In the operation of laser 6, emitted light generated by lasing section 51 propagates horizontally toward deflecting surface 57. The horizontally propagating light, as described above (FIGS. 5a 5b, and 5c), is mostly redirected towards bottom reflector 54 by deflecting surface 57. However, a small fraction of the emitted light is absorbed in active portion 52 of beam-deflecting section 51 while propagating toward deflecting surface 57. The amount of light absorbed is determined by factors such as the optical confinement factor and the length (in section 51) of active portion 52 preceding surface 57. This light absorption in active portion 52 generates photo-excited carriers. Since top electrode 53 does not extend over section 51, active portion 52 (in section 51) is not electrically pumped (i.e., is not itself lasing). Therefore, active portion 52 can function as a power-monitoring detector. The number of photo-excited carriers generated in active portion 52 is proportional to the laser power output. The generated photo-excited carriers are collected by electrode 61 producing a photocurrent proportional to laser output.

The processes for making individual elements of different embodiments of inventive laser device have been generally described above. The elements and the processes for making them were described in a particular sequence in the context of explaining the operation of the laser device. With this perspective view, it will be understood that this particular sequence may not necessarily be the sequence of process steps used in the fabrication of the laser devices. An illustrative sequence of process steps that may be used in the fabrication of the laser devices may, for example, be as follows:

prepare an epitaxial multiple-layer structure including, for example, upper and lower cladding layers and an active layer, on a semiconductor substrate that is transparent to light radiation at the lasing wavelength;

form lasing waveguides with top metal electrode contacts using conventional processes for making edge-emitting lasers;

etch light deflection surfaces designed for total internal reflection by either wet chemical etching or dry etching techniques;

thin the substrate by back lapping the substrate;

form back reflectors by repolishing the lapped back surface and then coating the polished surface with reflective metal layer;

define lasing and beam-deflection sections of laser devices by cleaving adjacent substrate pieces or by etching delimiting trenches between adjacent substrate pieces;

in the case of cleaved adjacent pieces, form holding structures using plated metal, resist, or epoxy to hold the lasing sections and the beam-deflection sections in close proximity.

form beam-shaping micro-optic lenses on top surfaces of the lasing sections and the beam-deflection sections; and

dice the wafer into individual surface-emitting laser devices or arrays of devices.

The sequence of process steps listed above is only illustrative and may be performed in any suitable order. In practice, some of the steps may be omitted, and additional steps that are not listed above may be included in the fabrication of the inventive laser devices.

It will be understood that the foregoing is only illustrative of the principles of the invention, and that various modifications can be made by those skilled in the art without departing from the scope and spirit of the invention.

The invention claimed is:

1. A semiconductor laser device structure having a first surface, comprising:
a lasing section containing a laser cavity that emits a light beam propagating in a horizontal direction substantially parallel to said first surface; and
a beam-deflecting section adjoining said lasing section, said beam-deflecting section comprising a plurality of reflective surfaces arranged in an array for redirecting said horizontally-propagating light beam to propagate in a substantially vertical direction toward said first surface.

2. The semiconductor laser device defined in claim 1 wherein said lasing section and said beam-deflecting section are mechanically joined.

3. The semiconductor laser device defined in claim 2 wherein said sections have edges that are substantially perpendicular to said horizontal surfaces, and wherein said sections are mechanically joined along said edges.

4. The semiconductor laser device defined in claim 3 wherein said edges are cleaved crystal facets.

5. The semiconductor laser device defined in claim 3 wherein said edges are etched facets.

6. The semiconductor laser device defined in claim 2 wherein said sections are mechanically joined by a common substrate.

7. The semiconductor laser device defined in claim 6 wherein said sections are delimited by a trench having substantially vertical etched sidewalls.

8. The semiconductor laser device defined in claim 1 wherein said array comprises;
a first deflecting surface facing said horizontally propagating light beam: and
a second deflecting surface facing upward toward said top surface,
wherein said first deflecting surface has an orientation angle with respect to the horizontal so that it reflects said horizontally-propagating light beam toward said second deflecting surface.

9. The semiconductor laser device of claim 8 wherein said second deflecting surface is a reflector formed on a bottom surface of said semiconductor laser device.

10. The semiconductor laser device of claim 8 wherein said orientation angle is such that said horizontally-propagating light beam undergoes total internal reflection toward said second deflecting surface.

11. The semiconductor laser device defined in claim 8 wherein said first deflecting surface is a crystallographically-terminating etch plane.

12. The semiconductor laser device defined in claim 11 wherein said etch plane is a side of a V-groove shaped etch pit.

13. The semiconductor laser device defined in claim 1 further comprising an optical lens disposed on said top surface wherein said lens modifies the beam profile of said vertically-propagating light beam.

14. The semiconductor laser device defined in claim 12 wherein said lens is a refractive lens.

15. The semiconductor laser device defined in claim 13 wherein said lens is made of resist material.

16. The semiconductor laser device defined in claim 12 wherein said lens is a diffractive lens.

17. The semiconductor laser device defined in claim 1 wherein said sections are made from semiconductor substrates on which epitaxial layers have been grown.

18. The semiconductor laser device defined in claim 17 wherein said substrates are transparent to radiation at the wavelengths of said emitted light beam.

19. The semiconductor laser device defined in claim 1 wherein said beam-deflecting section further comprises a power-monitoring detector.

20. The semiconductor laser device defined in claim 17 wherein said detector is a photodiode with a metal electrode deposited on said beam-deflecting section.

21. A method of fabricating a semiconductor laser device, comprising:
forming an epitaxial multiple-layer structure on a substrate that is transparent to a lasing wavelength, said multiple-layer structure comprising:
a first cladding layer;
an active waveguide layer; and
a second cladding layer;
forming at least a deflection surface that can deflect a light beam propagating in a horizontal direction in said waveguide layer toward the bottom surface of the substrate;
forming a reflective structure on the bottom of the substrate to upwardly reflect incident light;
forming a lasing section including a laser cavity with faceted ends;
forming a beam-deflecting section including said deflection surface; and
forming a beam-correction lens on the top surface of said beam-deflecting section.

22. The method of claim 19 wherein said forming a beam-correction lens comprises forming micro-optic lenses by resist reflow.

23. The method of claim 19 wherein said forming lasing and beam-deflection sections, comprise:
cleaving adjacent pieces of said substrate for use as said lasing section and said beam-deflection section; and
rejoining adjacent pieces along cleaved facets.

24. The method of claim 19 wherein said forming lasing and beam-deflection sections, comprise etching trenches in said multiple-layer structure to delimit said sections.

25. A semiconductor laser device generating a surface-emitted output beam from a first surface of said device, comprising:
means for generating a light beam substantially parallel to said first surface;
means for first redirecting said light beam toward a second surface of said device; and
means for next redirecting said light beam toward said first surface wherefrom said light beam emerges as said output beam.

26. The device defined in claim 25 wherein said means for first redirecting comprise means for reflecting said light beam.

27. The device defined in claim 26 wherein said means for reflecting comprise means for total internal reflection of said light beam.

28. The device defined in claim 25 further comprising means for applying beam-correction optics to modify a profile of said output beam.

29. The device defined in claim 28 wherein said means for applying comprises means disposed on said first surface.

30. The device defined in claim 25 further comprising means for monitoring an output power of said device.

31. The device defined in claim 30 wherein said means for monitoring comprise detector means integrated with said device.

32. A method for generating a surface-emitted output beam from a first surface of a semiconductor device, comprising:
generating a light beam substantially parallel to said first surface;
next, redirecting said light beam toward a second surface of said device; and
then, redirecting said light beam toward said first surface wherefrom said light beam emerges as said output beam.

33. The method defined in claim 32 wherein redirecting said light beam toward said second surface comprises reflecting said light beam off an etch plane.

34. The method defined in claim 32 wherein redirecting said beam toward said second surface comprises using the phenomenon of total internal reflection.

35. The method defined in claim 32 further comprising applying beam-correction optics to modify a beam-profile of said output beam.

36. The method defined in claim 35 wherein said applying comprises using a lens disposed on said first surface.

37. The method defined in claim 32 further comprising monitoring an output power of said device.

38. The method defined in claim 37 wherein said monitoring comprises using a power-monitoring detector integrated with said device.

39. A semiconductor laser device structure having a top surface, comprising:
a lasing section that emits a light beam substantially parallel to said top surface; and
a beam-deflecting section adjoining said lasing section, said beam-deflecting section including two surfaces arranged for reflecting said light beam so that it is substantially orthogonal to said top surface.

40. A semiconductor laser device structure having a first surface, comprising:
a lasing section that emits a light beam substantially parallel to said first surface; and
a beam-deflecting section for redirecting said light beam by total internal reflection.

41. The semiconductor laser device defined in claim 40 wherein said beam-deflecting section by further reflection redirects said total-internal reflected light beam toward said first surface.

42. A semiconductor laser device structure having top and bottom surfaces, comprising:
a lasing section that emits a light beam substantially parallel to said surfaces; and
a beam-deflecting section for redirecting said light beam toward said top surface, wherein an optical path length traversed by said light beam in said beam-deflecting section before emerging from said top surface includes the distance between said top and bottom surfaces.

43. The semiconductor laser device defined in claim 42 wherein said optical path length is at least about twice the distance between said surfaces.

44. A semiconductor laser device comprising a lasing section that emits a light beam coupled into an adjoining beam-deflecting section, said beam-deflecting section comprising a V-groove shaped etch pit positioned in the path of said light beam such that said light beam is reflected off a side of said V-groove shaped etch pit.

45. The semiconductor laser device defined in claim 44 wherein said side is oriented such that the angle of incidence of said light beam incident on said side is greater than the critical angle for total internal reflection.
